(19) United States
(12) Patent Application Publication
(10) Pub. No.: US 2026/0206370 A1
(43) Pub. Date: Jul. 16, 2026

(54) LIGHT-EMITTING DEVICE INCLUDING LOW-TEMPERATURE GROWN BUFFER ELECTRODE LAYER AND METHOD OF FABRICATING THE SAME

(71) Applicant: Korea Institute of Energy Technology, Jeollanam-do (KR)

(72) Inventors: Joon Seop KWAK, Jeollanam-do (KR); Yu Jung CHA, Jeollanam-do (KR); Chan PARK, Jeollanam-do (KR)

(21) Appl. No.: 19/399,640

(22) Filed: Nov. 25, 2025

(30) Foreign Application Priority Data
Jan. 13, 2025 (KR) 10-2025-0004526

(51) Int. Cl. H10H 20/832; H10H 20/01; H10H 20/825

(52) U.S. Cl. CPC H10H 20/835; H10H 20/032; H10H 20/825

(57) ABSTRACT

Disclosed is a light-emitting device including a substrate, a buffer electrode layer, nitride semiconductor layers, an active layer, and an electrode layer, wherein the buffer electrode layer simultaneously forms an ohmic contact with a nitride semiconductor layer and serves as a buffer layer for epitaxial growth. The buffer electrode layer is formed using curved-flight electron beam-based sputtering or electron beam-assisted sputtering, and these processes can be combined with electron beam annealing. In particular, the deposition is performed at an ultra-low pressure of 0.05 mTorr or less, enabling the formation of a high-quality thin film.

### CROSS-REFERENCE TO RELATED APPLICATION

This application claims priority to Korean Patent Application No. 10-2025-0004526, filed on January 13, 2025 in the Korean Intellectual Property Office, the disclosure of which is incorporated herein by reference.

### BACKGROUND OF THE DISCLOSURE

### Field of the Disclosure

The present disclosure relates to a light-emitting device, and more particularly, to a micro-LED structure that is directly connected to a driving circuit and is formed by sputter thin film growth. Specifically, the present disclosure relates to a light-emitting device equipped with a buffer electrode layer that forms an ohmic contact with an n-type or p-type nitride semiconductor layer while simultaneously serving as a buffer layer for epitaxial growth, and a method of fabricating the light-emitting device at a low temperature.

The present disclosure presents a technical solution that can improve the performance of micro-LED displays and simplify the fabrication process by providing a technology that can form a buffer electrode layer with excellent crystallinity through a low-temperature growth process while preventing the deterioration of a substrate.

This work was supported by the Samsung Research Funding & Incubation Center for Future Technology (Project Number: SRFC-MA2402-05).

### Description of the Related Art

In the field of light-emitting devices, particularly micro-LED displays, it is very important to form a high-quality nitride semiconductor layer.

In related micro-LED manufacturing technology, a nitride semiconductor layer was grown through a high-temperature Metal Organic Chemical Vapor Deposition (MOCVD) process. However, this high-temperature process has a problem in that it restricts the use of low-temperature substrates such as glass or polymer, and may cause the deterioration of a driving circuit pre-formed on the substrate.

To solve these problems, low-temperature growth methods such as sputtering have been proposed, but there was a limitation in that it was difficult to form a nitride semiconductor layer with excellent crystallinity using existing sputtering methods.

In particular, a suitable buffer layer is required for the growth of a nitride semiconductor layer, but a buffer layer grown at a low temperature generally has poor crystallinity and unfavorable interface characteristics, making it difficult to grow a high-quality nitride semiconductor layer.

Furthermore, in existing light-emitting device structures, a buffer layer and an electrode layer were formed separately, which complicated the manufacturing process and increased costs. Particularly, in cases requiring fine patterns such as in micro-LED displays, a problem of decreased yield also occurred due to alignment issues between a buffer layer and an electrode layer.

Meanwhile, in the existing sputtering process, a high deposition pressure shortens the mean free path of sputtered particles, which in turn reduces the energy of particles reaching the substrate, creating a problem in which it is difficult to form a high-quality thin film.

Additionally, the high deposition pressure also caused a decrease in electrical characteristics by increasing the incorporation of impurities.

Accordingly, there has been a demand for the development of a new technology that can form a buffer layer with excellent crystallinity even at low temperatures, and can simultaneously perform the function of an electrode. In particular, the need has emerged for a new deposition technology that enables sputtering under ultra-low pressures and allows for in-situ processing to improve crystallinity.

### Related Art Document

### Patent Document

Korean Patent Application Publication No. 10-2023-0033592 (published on March 08, 2023)

### SUMMARY OF THE DISCLOSURE

Therefore, the present disclosure has been made in view of the above problems, and it is an object of the present disclosure to form a buffer electrode layer having excellent crystallinity even at a low temperature.

It is another object of the present disclosure to form a stable plasma even at an ultra-low pressure (0.05 mTorr or less) and deposit a high-quality thin film, by using electron beam-based sputtering.

It is still another object of the present disclosure to simplify the manufacturing process and reduce manufacturing costs, by forming a single layer or laminated structure that simultaneously performs the functions of a buffer layer and an electrode layer.

It is still another object of the present disclosure to provide a light-emitting device having a new structure that can simultaneously form an excellent ohmic contact with a nitride semiconductor layer and serve as a buffer layer for epitaxial growth.

It is still another object of the present disclosure to provide a technology capable of directly integrating a driving circuit and a light-emitting device on a substrate having a melting point at a low temperature, such as glass or a polymer, or on an amorphous layer such as SiO₂.

It is still another object of the present disclosure to form at least one of a buffer electrode layer and nitride semiconductor layer having improved crystallinity, by applying a combination of a curved-flight electron beam and electron beam annealing.

It is still another object of the present disclosure to realize a light-emitting device optimized for both a Direct-Connected Structure (DCS) and a Direct-Connected Inversion Structure (DCIS) by providing a buffer electrode layer material suitable for each of an n-type nitride semiconductor layer and a p-type nitride semiconductor layer.

It is yet another object of the present disclosure to fabricate a high-quality nitride semiconductor-based light-emitting device through a low-temperature process while preventing deterioration of a substrate.

In accordance with an aspect of the present disclosure, the above and other objects can be accomplished by the provision of a light-emitting device, including a substrate; and a buffer electrode layer that is formed on the substrate and includes at least one of a metal having a hexagonal crystal structure, an n-type transparent conductive oxide, and a heavily doped n-type nitride. On the buffer electrode layer, an n-type nitride semiconductor layer, an active layer, a p-type nitride semiconductor layer, and a p-type electrode layer may be sequentially formed. In particular, the buffer electrode layer may form an ohmic contact with the n-type nitride semiconductor layer, and simultaneously perform the function of a buffer layer for the growth of the n-type nitride semiconductor layer.

In accordance with another aspect of the present disclosure, there is provided a light-emitting device, including a substrate; and a buffer electrode layer that is formed on the substrate and includes at least one of a metal having a high work function, a metal having a hexagonal crystal structure, and a p-type transparent conductive oxide.

On the buffer electrode layer, a p-type nitride semiconductor layer, an active layer, an n-type nitride semiconductor layer, and an n-type electrode layer may be sequentially formed. The buffer electrode layer may form an ohmic contact with the p-type nitride semiconductor layer, and simultaneously serve as a buffer layer for the epitaxial growth of the p-type nitride semiconductor layer.

The buffer electrode layer according to an embodiment may include at least one metal having a hexagonal crystal structure selected from the group consisting of Ti, Zr, Hf, Co, Ru, Zn, Be, Os, Sc, and Y. Alternatively, it may include an n-type transparent conductive oxide containing ZnO doped with Al.

The light-emitting device according to an embodiment may further include a reflective layer, such as Ag, under the buffer electrode layer.

Furthermore, the p-type nitride semiconductor layer may have a heterojunction structure including a p-type zinc oxide layer and a p-type gallium nitride layer, which can improve hole injection efficiency and increase external quantum efficiency.

In accordance with yet another aspect of the present disclosure, there is provided a method of manufacturing a light-emitting device, the method including: forming a buffer electrode layer on a substrate using electron beam-based sputtering. Subsequently, a first nitride semiconductor layer, an active layer, a second nitride semiconductor layer, and an electrode layer may be sequentially formed on the buffer electrode layer.

The electron beam-based sputtering according to an embodiment may be performed by applying curved-flight electron beam-based sputtering, electron beam-assisted sputtering, or a combination of these with electron beam annealing, and in the case of curved-flight electron beam-based sputtering, it may be performed at an ultra-low pressure of 0.05 mTorr or less.

Furthermore, the buffer electrode layer, the first nitride semiconductor layer, the active layer, and the second nitride semiconductor layer may be formed by the electron beam-based sputtering process, and the substrate may be maintained at a temperature of 200°C or less.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 illustrates a light-emitting device including a Direct-Connected Structure (DCS) according to an embodiment of the present disclosure;

FIG. 2 illustrates a light-emitting device including a Direct-Connected Inversion Structure (DCIS) according to another embodiment of the present disclosure;

FIGS. 3 and 4 are sectional views illustrating a fabrication process of a display based on the light-emitting device with the DCS according to an embodiment of the present disclosure;

FIGS. 5 and 6 illustrate a fabrication process of a display based on the

light-emitting device with the DCIS structure according to another embodiment of the present disclosure;

FIG. 7 is a sectional view illustrating an electron beam-based sputtering apparatus according to an embodiment of the present disclosure;

FIG. 8 is a plan view illustrating a cluster-type electron beam-based sputtering apparatus 500 according to an embodiment of the present disclosure;

FIG. 9 is a graph illustrating a change in substrate temperature during an electron beam annealing process over time;

FIG. 10 is a graph illustrating a change in Root Mean Square (RMS) roughness of an Al₂O₃ thin film formed on a PI substrate according to electron beam DC power;

FIG. 11 compares transmission electron microscope (TEM) images and electron diffraction patterns of an ITO thin film deposited on a glass substrate at room temperature (RT) before and after electron beam annealing (EBA) treatment;

FIG. 12 is a graph illustrating X-ray diffraction (XRD) patterns according to the deposition pressure of GaN thin films deposited on a glass substrate without a buffer layer;

FIG. 13 compares the surface characteristics of thin films formed by RF sputtering, ex-situ electron beam annealing (EBA), and in-situ electron beam annealing processes using atomic force microscope (AFM) images and scanning electron microscope (SEM) images;

FIG. 14 illustrates the energy band diagram of a p-ZnO/p-GaN/p-AlGaN EBL/InGaN-GaN MQW/n-GaN LED structure; and

FIG. 15 is a flowchart illustrating a method of fabricating the light-emitting device according to an embodiment of the present disclosure.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms "comprise" and/or "comprising", when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular forms "a", "an" and "the" are intended to include the plural forms as well, unless context clearly indicates otherwise.

Although terms used in the specification are selected from terms generally used in related technical fields, other terms may be used according to technical development and/or due to change, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Meanwhile, in the following description of the present disclosure, a detailed description of known functions and configurations incorporated herein will be omitted when it may make the subject matter of the present disclosure unclear. The terms used in the specification are defined in consideration of functions used in the present disclosure, and can be changed according to the intent or conventionally used methods of clients, operators, and users. Accordingly, definitions of the terms should be understood on the basis of the entire description of the present specification.

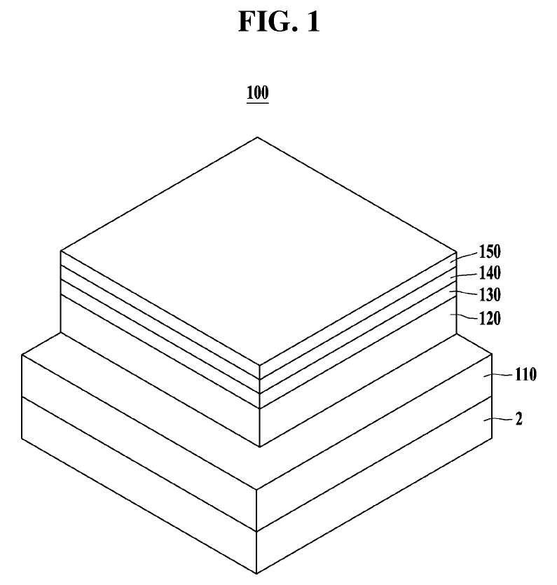

FIG. 1 illustrates a light-emitting device including a Direct-Connected Structure (DCS) according to an embodiment of the present disclosure.

Referring to FIG. 1, a light-emitting device 100 according to an embodiment of the present includes a structure sequentially laminated on a substrate 2.

The substrate 2 may be a glass substrate, which indicates that the present disclosure may be manufactured through a low-temperature process.

According to an embodiment, the substrate 2 may include any one of a substrate having a low-temperature melting point, which is one of a glass substrate and a polymer substrate, a substrate including an amorphous layer, and a metal substrate. The amorphous oxide layer may include SiO₂, and the metal substrate may include at least one of Mo and Cu.

A buffer electrode layer 110 is formed on the substrate 2. The buffer electrode layer 110 includes at least one of a metal having a hexagonal crystal structure, an n-type transparent conductive oxide, and a heavily doped n-type nitride.

In particular, the buffer electrode layer 110 forms an ohmic contact with an n-type nitride semiconductor layer 120 formed thereon, and simultaneously serves as a buffer layer for epitaxial growth.

The buffer electrode layer 110 may be formed by an electron beam-based sputtering method such as curved-flight electron beam-based sputtering, electron beam-assisted sputtering, or a combination of these with electron beam annealing, and the deposition is performed at an ultra-low pressure of 0.05 mTorr or less. These process conditions may minimize the incorporation of impurities and improve the crystallinity of the thin film.

An active layer 130 of an InGaN/GaN multi-quantum well (MQW) structure may be formed on the n-type nitride semiconductor layer 120. The active layer 130 is the core light-emitting region of the light-emitting device and generates light through the recombination of electrons and holes.

A p-type nitride semiconductor layer 140 is formed on the active layer 130, and a p-type electrode layer 150 is formed on the p-type nitride semiconductor layer 140. The p-type electrode layer 150 may be composed of a transparent electrode and allow light generated in the active layer 130 to be effectively emitted upwards.

As illustrated in FIG. 1, the buffer electrode layer 110 may be formed under an ultra-low pressure using electron beam-based sputtering, and may minimize the incorporation of impurities and improve the crystallinity of the thin film.

Furthermore, a thin-film transistor array and a reflective layer (not shown) may be additionally formed between the substrate 2 and the buffer electrode layer 110, enabling application as a display device.

Each layer of the light-emitting device 100 according to an embodiment of the present disclosure shown in FIG. 1 may be designed to have an optimized thickness and composition. Through this, high-efficiency light-emitting characteristics and excellent electrical characteristics may be simultaneously realized.

In addition, a structure capable of front-side emission may be realized through the p-type electrode layer 150 that is a transparent electrode. This may include characteristics that are very suitable for display applications.

The light-emitting device 100 according to an embodiment of the present disclosure has a Direct-Connected Structure (DCS) sequentially laminated on the substrate 2. The DCS is a structure that directly and electrically connects an electrode of a thin-film transistor and a buffer layer, wherein the buffer electrode layer 110, which simultaneously performs the functions of an n-type electrode and a buffer layer, plays a key role.

The buffer electrode layer 110 formed on the substrate 2 is designed to simultaneously perform the role of forming an ohmic contact with the n-type nitride semiconductor layer and the role of a buffer layer for epitaxial growth. This is possible because the buffer electrode layer 110 is configured to include at least one of a metal having a hexagonal crystal structure, an n-type transparent conductive oxide, or a heavily doped n-type nitride.

The buffer electrode layer 110 should simultaneously satisfy appropriate work function characteristics for forming an ohmic contact with the upper n-type nitride semiconductor layer 120 and lattice matching characteristics for the crystal growth of the n-type nitride semiconductor layer 120.

The buffer electrode layer 110 may include a laminated structure of an n-type transparent conductive oxide layer laminated on a metal layer having a hexagonal crystal structure, and, according to an embodiment, may also include a laminated structure of a metal layer having a hexagonal crystal structure laminated on an n-type transparent conductive oxide layer.

Furthermore, according to an embodiment, the buffer electrode layer 110 may include a laminated structure in which an n-type transparent conductive oxide layer, a metal layer having a hexagonal crystal structure, and an n-type transparent conductive oxide layer are sequentially laminated, and may also include a laminated structure in which a metal layer having a hexagonal crystal structure, an n-type transparent conductive oxide layer, and a metal layer having a hexagonal crystal structure are sequentially laminated.

For example, the buffer electrode layer 110 may include at least one metal having a hexagonal crystal structure selected from the group consisting of Ti, Zr, Hf, Co, Ru, Zn, Be, Os, Sc, and Y, and the buffer electrode layer 110 may also include an n-type transparent conductive oxide containing ZnO doped with Al.

According to an embodiment, the buffer electrode layer 110 may include a material having a difference of 0.1 Å or less from the a-direction lattice constant of the n-type nitride semiconductor layer 120.

The p-type nitride semiconductor layer 140 may include a heterojunction structure including a p-type gallium nitride layer and a p-type zinc oxide layer formed on the p-type gallium nitride layer, and the heterojunction structure may improve hole injection efficiency and increase external quantum efficiency.

In the DCS structure illustrated in FIG. 1, the n-type nitride semiconductor layer 120, the active layer 130, the p-type nitride semiconductor layer 140, and the p-type electrode layer 150 are sequentially laminated, and in particular, the p-type electrode layer 150 may be formed as a transparent electrode to provide a structure capable of front-side emission.

In a front-side emission display structure, a thin-film transistor array and a reflective layer may be additionally configured between the substrate 2 and the buffer electrode layer 110, which may be formed in a structure of a TFT array/reflective layer/buffer electrode layer.

The DCS of the light-emitting device 100 according to an embodiment of the present disclosure shown in FIG. 1 may simplify the manufacturing process by integrating the functions of the electrode and the buffer layer into a single layer.

According to an embodiment, at least one of the buffer electrode layer 110, the n-type nitride semiconductor layer 120, the active layer 130, and the p-type nitride semiconductor layer 140 may be formed by the electron beam-based sputtering process.

Furthermore, since the buffer electrode layer 110 directly forms an ohmic contact with the n-type nitride semiconductor layer 120, contact resistance may be minimized, and this structural feature is particularly well-suited for high-resolution, high-efficiency display applications such as micro-LED displays.

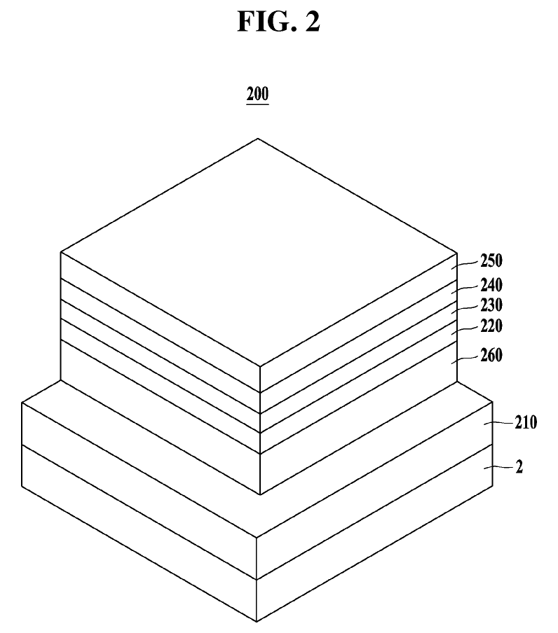

FIG. 2 illustrates a light-emitting device including a Direct-Connected Inversion Structure (DCIS) according to another embodiment of the present disclosure.

Referring to FIG. 2, a light-emitting device 200 according to another embodiment of the present disclosure includes a structure sequentially laminated on a substrate 2.

The substrate 2 may be a glass substrate, which indicates that the electron beam-based sputtering process of the present disclosure may be performed at a low temperature of 200°C or less.

According to an embodiment, the substrate 2 may include any one of a substrate having a low-temperature melting point, which is one of a glass substrate and a polymer substrate, a substrate including an amorphous layer, and a metal substrate. The amorphous oxide layer may include SiO₂, and the metal substrate may include at least one of Mo and Cu.

A buffer electrode layer 210 is formed on the substrate 2. In this embodiment, the buffer electrode layer 210 includes at least one of a metal having a high work function, a metal having a hexagonal crystal structure, and a p-type transparent conductive oxide.

For example, the buffer electrode layer 210 may be at least one material having a high metal work function selected from the group consisting of Pd, Ir, Pt, Au, and Ni.

Furthermore, the buffer electrode layer 210 may be at least one p-type transparent conductive oxide selected from the group consisting of Cu₂O, CuMO₂ (M=Cr, Sc, Al, Y, B, In or Ga), ZnM₂O₄ (M=Co, Rh, or Ir), NiO, SnO, V₂O₃, Cr₂O₃, SrCu₂O₂, and La₁-ₓSrₓCrO₃.

The buffer electrode layer 210 forms an ohmic contact with a p-type zinc oxide layer 260 and p-type nitride semiconductor layer 220 formed thereon, while simultaneously serving as a buffer layer for epitaxial growth.

In another embodiment of the present disclosure, the p-type zinc oxide layer 260 may be formed on the buffer electrode layer 210, and the p-type nitride semiconductor layer 220 may be formed thereon.

In another embodiment of the present disclosure, the p-type zinc oxide layer 260 may be formed on the buffer electrode layer 210, and the p-type nitride semiconductor layer 220 may be formed thereon. The heterojunction structure of the p-type zinc oxide layer 260 and the p-type nitride semiconductor layer 220 of the light-emitting device 200 according to another embodiment of the present disclosure may improve hole injection efficiency and increase external quantum efficiency.

An active layer 230 having an InGaN/GaN multi-quantum well structure is formed on the p-type nitride semiconductor layer 220. The active layer 230 functions as the core light-emitting region of the light-emitting device.

An n-type nitride semiconductor layer 240 is formed on the active layer 230, and an n-type electrode layer 250 is formed on the uppermost part. The n-type electrode layer 250 includes a transparent conductive oxide to provide a structure capable of front-side emission.

The light-emitting device 200 of this embodiment has an inverted structure compared to the light-emitting device 100 shown in FIG. 1. This Direct-Connected Inversion Structure (DCIS) has an advantage in that hole injection efficiency may be improved through the introduction of the p-type zinc oxide layer 260.

The buffer electrode layer 210 may be formed by an electron beam-based sputtering method such as curved-flight electron beam-based sputtering, electron beam-assisted sputtering, or a combination of these with electron beam annealing, and the deposition is performed at an ultra-low pressure of 0.05 mTorr or less. These process conditions may minimize the incorporation of impurities and improve the crystallinity of the thin film.

Furthermore, in the structure of the light-emitting device 200 according to another embodiment, a thin-film transistor array and a reflective layer may be additionally formed between the substrate 2 and the buffer electrode layer 210, which may provide a structure very suitable for micro-LED display applications.

In the DCIS structure of the light-emitting device 200 according to another embodiment of the present disclosure shown in FIG. 2, the active layer 230, the n-type nitride semiconductor layer 240, and the n-type electrode layer 250 are sequentially laminated on the p-type nitride semiconductor layer 220. In particular, the n-type electrode layer 250 is formed of a transparent conductive oxide to provide a structure capable of front-side emission.

According to an embodiment, at least one of the buffer electrode layer 210, the p-type nitride semiconductor layer 220, the active layer 230, and the n-type nitride semiconductor layer 240 may be formed by the electron beam-based sputtering process.

In the front-side emission display structure, a thin-film transistor array and a reflective layer may be additionally configured between the substrate 2 and the buffer electrode layer 210.

A primary advantage of the DCIS structure is that the efficiency of hole injection into the p-type nitride semiconductor layer 220 may be improved through the introduction of the p-type zinc oxide layer 260.

Furthermore, by growing the p-type zinc oxide layer 260 on the buffer electrode layer 210, the crystallinity of the p-type nitride semiconductor layer 220 may be improved.

This provides more advantageous characteristics in terms of crystallinity than the existing p-type transparent conductive oxide/p-type nitride semiconductor layer structure.

In addition, the DCIS structure of the light-emitting device 200 according to another embodiment of the present disclosure is suitable for high-resolution micro-LED display applications of 300 ppi or higher, such as smart watches and mobile phones, and the front-side emission efficiency may be further improved by applying a reflective layer to the p-type electrode component.

The DCIS structure of the light-emitting device 200 according to another embodiment of the present disclosure, similar to the DCS of FIG. 1, may be fabricated through an electron beam-based sputtering process at a low temperature of 200°C or less, and thus has the advantage of being applicable to various substrates.

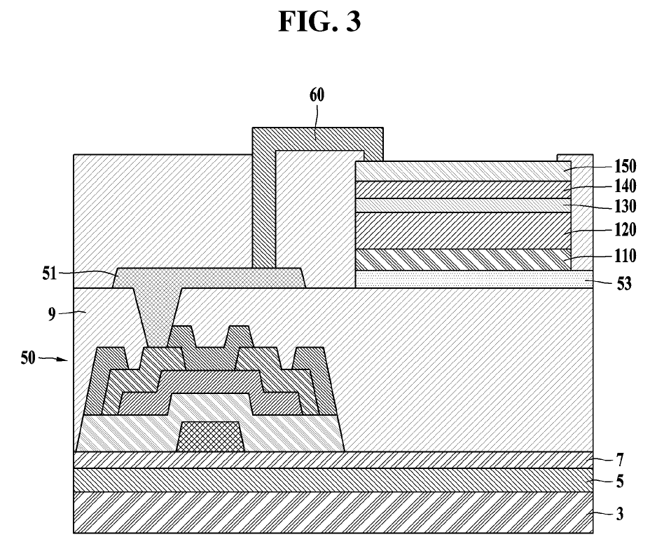

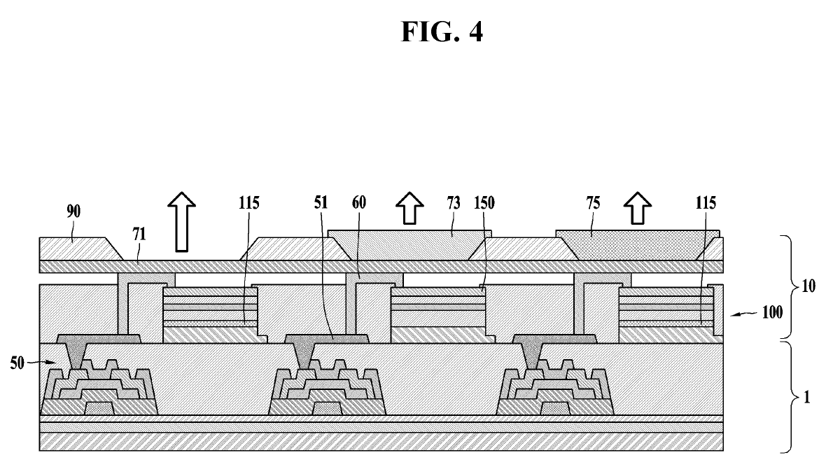

FIGS. 3 and 4 are sectional views illustrating a fabrication process of a display based on the light-emitting device with the Direct-Connected Structure (DCS) according to an embodiment of the present disclosure.

Referring to FIGS. 3 and 4, the display based on the light-emitting device with the DCS according to an embodiment of the present disclosure may be divided into a lower driving circuit substrate 1 and an upper light-emitting device layer 10.

A glass substrate 3 is disposed under the driving circuit substrate 1, and the glass substrate 3 serves as a mechanical support for the entire device.

On the glass substrate 3, a PI layer 5 made of a polyimide material is formed, which serves to protect the lower structure from thermal and mechanical stress that may occur in subsequent processes.

Furthermore, a buffer layer 7 may be formed on the PI layer 5. The buffer layer 7 prevents impurity diffusion from below to stabilize the characteristics of a thin-film transistor to be formed thereon and contributes to improving the crystallinity of the upper device.

A thin-film transistor 50 formed on the buffer layer 7 has a basic structure composed of a gate, a gate insulating layer, a channel, a source, and a drain. This thin-film transistor 50 serves as a key driving element that independently controls the light emission of each pixel.

The planarization layer 9 may alleviate a step height difference caused by the thin-film transistor 50. The planarization layer 9 enables uniform deposition of the light-emitting device layer formed in a subsequent process, thereby improving the reliability of the device.

According to an embodiment, a pixel electrode 51 formed on the planarization layer 9 is electrically connected to the source or drain of the thin-film transistor 50 and serves as a path for transmitting a driving voltage to the light-emitting device.

A light-emitting device layer 10 is a key element of the DCS, and on a common cathode layer 53 made of an ITO material, the buffer electrode layer 110, the n-type nitride semiconductor layer 120, the active layer 130, the p-type nitride semiconductor layer 140, and a p-type transparent electrode layer 150 are sequentially laminated.

In particular, the buffer electrode layer 110 has a unique structural feature of simultaneously performing the role of forming an ohmic contact with the n-type nitride semiconductor layer 120 and the role of a buffer layer for crystal growth, as shown in FIG. 1.

A wiring 60 may provide an electrical connection between respective layers and electrically connects the pixel electrode 51 and the light-emitting device layer 10 to enable the direct driving of the light-emitting device 100 that is the core of the DCS according to an embodiment of the present disclosure.

FIG. 4 illustrates a color conversion structure for implementing a full-color display, wherein a light-emitting region 71 may be formed on the light-emitting device layer 10.

In the light-emitting region 71, a first quantum dot color conversion layer 73 and a second quantum dot color conversion layer 75, which have different color conversion characteristics, may be disposed. The first quantum dot color conversion layer 73 and the second quantum dot color conversion layer 75 may convert blue light generated from the light-emitting device 100 with the DCS according to an embodiment of the present disclosure into red or green light, thereby enabling the implementation of full color.

A light absorption layer 90 is disposed between the quantum dot color conversion layers. This serves to prevent optical interference between adjacent pixels and improve color purity.

Through the structure shown in FIG. 4, a high-quality full-color display may be implemented, and in particular, it may be manufactured by a low-temperature process (200°C or less) using electron beam-based sputtering to implement a light-emitting device with excellent characteristics while preventing the deterioration of the lower structure.

The display based on the light-emitting device with the Direct-Connected Structure (DCS) according to an embodiment of the present disclosure may be applied to various application fields such as TVs and mobile displays, and may have structural features that are particularly well-suited for manufacturing 100 ppi-class micro-LED displays and transparent displays.

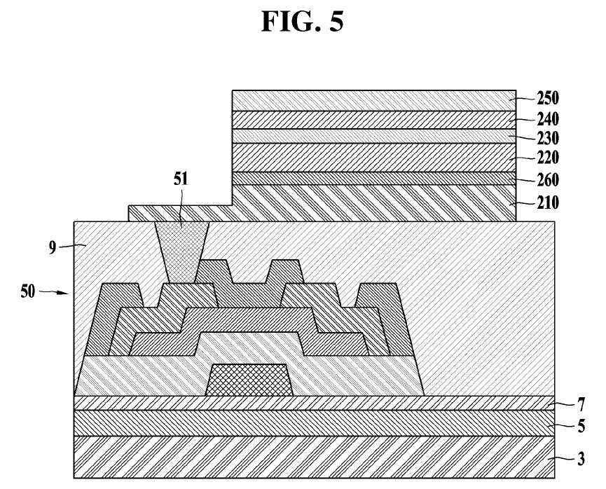

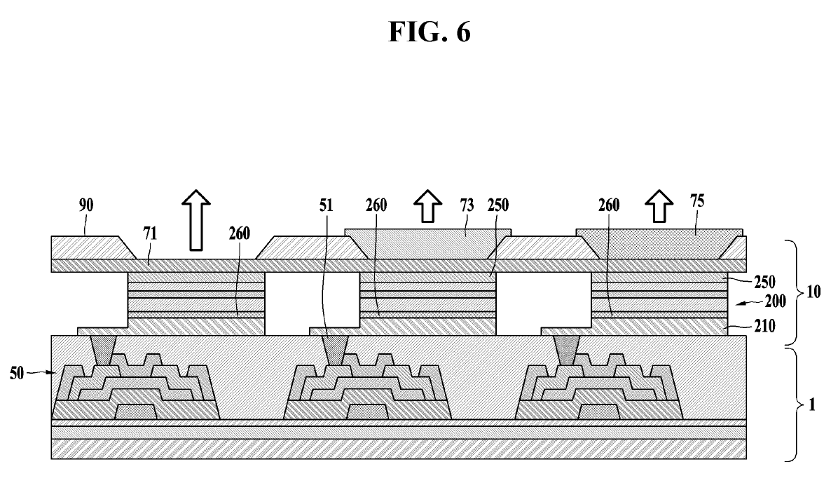

FIGS. 5 and 6 illustrate a fabrication process of a display based on the light-emitting device with the Direct-Connected Inversion Structure (DCIS) according to another embodiment of the present disclosure.

Referring to FIGS. 5 and 6, a display based on the light-emitting device with the DCIS structure according to another embodiment of the present disclosure may be divided into a lower driving circuit substrate 1 and an upper light-emitting device layer 10.

The glass substrate 3 serves as a mechanical support for the entire device, and due to its transparent nature, it may become the basis for implementing a double-sided emission display.

Furthermore, the PI layer 5 made of a polyimide material with excellent heat resistance and flexibility is formed on the glass substrate 3. The PI layer 5 serves as a buffer layer that effectively protects the lower structure from thermal stress and mechanical deformation occurring in subsequent processes.

The buffer layer 7 formed on the PI layer 5, in addition to its planarization function, plays a key role in blocking impurity diffusion from below and stabilizing the electrical characteristics of the thin-film transistor to be formed thereon.

In particular, since the crystallinity and surface characteristics of the buffer layer 7 directly affect the performance of the upper device, precise process control is required.

The thin-film transistor 50 is precisely formed on the buffer layer 7. The thin-film transistor 50 has a complete transistor structure including a gate, a gate insulating layer, a channel, a source, and a drain, and serves as an active driving element that precisely controls the independent driving of each light-emitting device.

The planarization layer 9 effectively planarizes a surface step height difference caused by the thin-film transistor 50, thereby enabling the uniform formation of the upper light-emitting device.

The buffer electrode layer 210 of the light-emitting device 200 with the DCIS according to another embodiment of the present disclosure performs a dual function as a p-type electrode and a buffer layer. It is formed to include at least one of a metal having a high work function, a metal having a hexagonal crystal structure, and a p-type transparent conductive oxide.

On the buffer electrode layer 210, the p-type zinc oxide layer 260 is formed, which forms an efficient heterojunction structure with the subsequent p-type nitride semiconductor layer 220. The buffer electrode layer 210 may significantly improve hole injection efficiency and increase external quantum efficiency.

FIG. 6 illustrates in more detail a process of implementing a full-color display using the DCIS structure according to another embodiment of the present disclosure.

The DCIS-based light-emitting device 200 may include a structure laminated in the order of the p-type zinc oxide layer 260, the p-type nitride semiconductor layer 220, the active layer 230, the n-type nitride semiconductor layer 240, and an n-type transparent electrode layer 250.

In particular, the active layer 230 is designed with an InGaN/GaN multi-quantum well structure, enabling efficient photon generation.

In the display based on the light-emitting device with the DCIS structure according to another embodiment of the present disclosure, the light generated from the light-emitting device 200 may be emitted through the light-emitting region 71 and may be precisely converted to a desired color by quantum dot color conversion layers 73 and 75 disposed thereon.

In the display based on the light-emitting device with the DCIS structure according to another embodiment of the present disclosure, the light-emitting device 200 may be fabricated by an electron beam-based sputtering process at a low temperature of 200°C or less.

In particular, deposition at an ultra-low pressure of 0.05 mTorr or less may minimize impurity incorporation and significantly improve the crystallinity of the thin film. This provides characteristics that are very suitable for high-resolution micro-LED displays of 300 ppi or higher, such as smart watches and mobile phones, and may have the significant advantage of further improving front-side emission efficiency by applying a reflective layer (not shown) to the p-type electrode component.

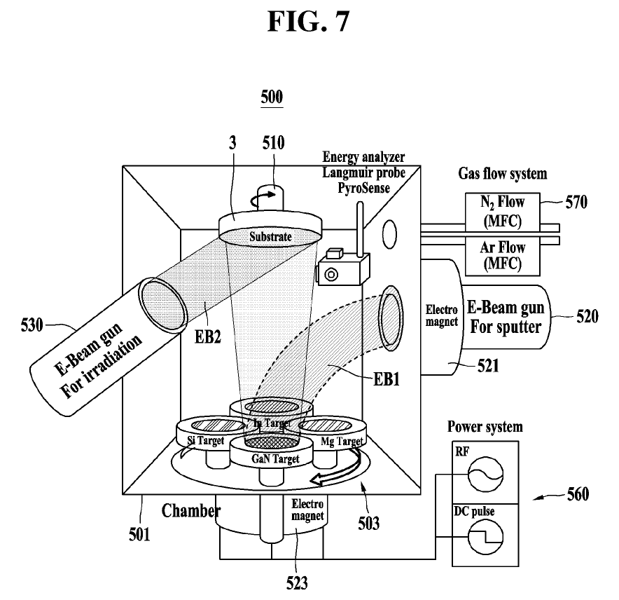

FIG. 7 is a sectional view illustrating an electron beam-based sputtering apparatus according to an embodiment of the present disclosure, and specifically illustrates the structure of a special deposition apparatus that can form a high-quality buffer electrode layer at a low temperature.

Referring to FIG. 7, an electron beam-based sputtering apparatus 500 includes various components precisely designed within a main chamber 501 The chamber 501 is designed with a structure that can maintain an ultra-high vacuum, and a substrate holder 510 for fixing the substrate 3 is installed inside.

The substrate holder 510 is designed to stably fix the substrate 3 and maintain it in a precise position, and has a rotatable structure for uniform deposition on the substrate.

Various analysis devices such as an energy analyzer, a Langmuir probe, and a PyroSense are provided within the chamber 501. The energy analyzer can measure the energy distribution of particles in the plasma in real-time, and the Langmuir probe monitors the density and temperature of the plasma. The PyroSense precisely measures the temperature of a substrate, enabling the accurate control of a low-temperature process condition of 200°C or less.

An electron gun system of the electron beam-based sputtering apparatus 500 is very precisely designed. An annealing electron gun 530 irradiates an electron beam EB2 toward the substrate to control the substrate temperature and the characteristics of the deposited thin film. The sputtering electron gun 520 performs sputtering by irradiating an electron beam EB1 toward a target. The electron beam of each electron gun is controlled by precise electromagnet systems 521 and 523, through which a curved-flight path may be formed.

A target part 503 is composed of a rotatable multi-target system. Various target materials such as an Si target, an Mg target, and a GaN target may be mounted, and a desired target may be precisely moved to the deposition position through a rotation mechanism controlled by an electromagnet 523. This structure enables the formation of a multilayer structure of the buffer electrode layer or the continuous deposition of various materials.

A gas supply system includes an MFC system capable of very precise flow rate control. A nitrogen flow controller 570 and an argon flow controller may precisely control respective gas flow rates, thereby enabling stable plasma formation at an ultra-low pressure (0.05 mTorr or less).

A power system 560 may include an RF power source and a DC pulse power source. The RF power source is responsible for the stable generation and maintenance of plasma, and the DC pulse power source is applied to the target to control sputtering efficiency. This dual power system enables precise process control under various deposition conditions.

The electron beam-based sputtering apparatus 500 implements the curved-flight electron beam-based sputtering technology. It has a structure in which an electron beam travels in a curved form along a magnetic field path formed by an emission electromagnet and a steering electromagnet and irradiates a target. This curved-flight structure enables stable plasma formation even at an ultra-low pressure, which significantly increases the mean free path of sputtered particles, enabling the formation of a high-quality thin film.

The electron beam-based sputtering apparatus 500 may grow the various layers required for manufacturing the aforementioned light-emitting devices with the DCS or DCIS with high quality. In particular, it may form a buffer electrode layer composed of a metal having a hexagonal crystal structure, an n-type or p-type transparent conductive oxide, etc., with excellent quality even at low temperatures, and thus may serve as an essential piece of process equipment for manufacturing micro-LED displays.

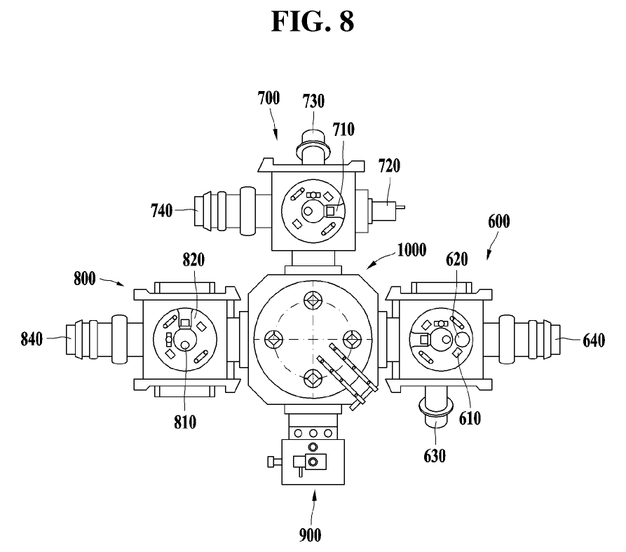

FIG. 8 is a plan view illustrating a cluster-type electron beam-based sputtering apparatus 500 according to an embodiment of the present disclosure.

Referring to FIG. 8, the cluster-type electron beam-based sputtering apparatus may have a structure in which a buffer electrode layer deposition chamber 600, a semiconductor layer deposition chamber 700, an RF sputtering chamber 800, and a load-lock chamber 900 are radially arranged around a transfer chamber 1000.

The buffer electrode layer deposition chamber 600 may form a buffer electrode layer made of a metal having a hexagonal crystal structure, or an n-type or p-type transparent conductive oxide. Inside the buffer electrode layer deposition chamber 600, a first substrate holder 610 is installed, and a first sputtering electron beam gun 620 and a first annealing electron beam gun 630 perform the sputtering and annealing processes, respectively. The high-vacuum environment of a chamber 600 is maintained by a first turbo pump 640.

In the semiconductor layer deposition chamber 700, an n-type nitride semiconductor layer, an active layer, and a p-type nitride semiconductor layer are sequentially formed. A second substrate holder 710 inside the semiconductor layer deposition chamber 700 precisely fixes the substrate, and a second sputtering electron beam gun 720 and a second annealing electron beam gun 730 may be installed. A second turbo pump 740 provides an ultra-high vacuum environment required for semiconductor deposition.

The RF sputtering chamber 800 is responsible for the formation of a transparent electrode layer. A third substrate holder 810 and an RF sputter gun 820 are installed, and a third turbo pump 840 maintains an appropriate degree of vacuum.

The central transfer chamber 1000 is responsible for substrate transfer between respective process chambers, and loading and unloading of the substrate are performed through the lower load-lock chamber 900. This cluster structure allows for continuous process execution without breaking the vacuum, and is effective in improving interface characteristics and preventing impurity incorporation.

The chambers have independent vacuum exhaust systems, so that a vacuum level optimized for each process may be maintained. In particular, stable plasma formation is possible even at an ultra-low pressure of 0.05 mTorr or less, and a high-quality thin film may be formed while preventing the deterioration of the substrate through a low-temperature process of 200°C or less.

Through the cluster-type electron beam-based sputtering apparatus of the present disclosure, all layers for the light-emitting devices with DCS or DCIS may be continuously formed.

For example, as shown in FIG. 1, at least one of the buffer electrode layer 110, the n-type nitride semiconductor layer 120, the active layer 130, and the p-type nitride semiconductor layer 140 may be formed through the electron beam-based sputtering apparatus.

Furthermore, as shown in FIG. 2, at least one of the buffer electrode layer 210, the p-type nitride semiconductor layer 220, the active layer 230, and the n-type nitride semiconductor layer 240 may be formed through the electron beam-based sputtering equipment.

In particular, a high-quality thin film may be stably manufactured through a process combining electron beam-based sputtering and annealing.

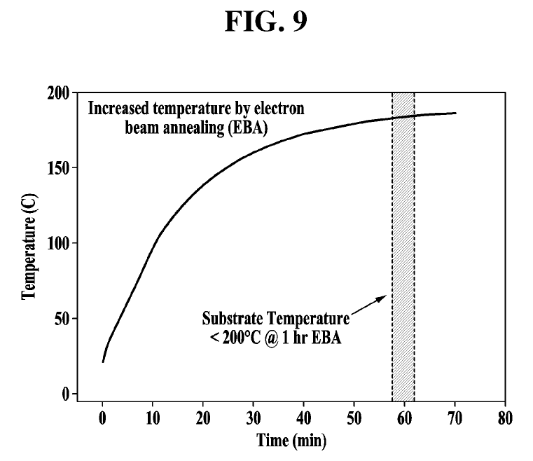

FIG. 9 is a graph illustrating a change in substrate temperature during an electron beam annealing process over time.

Referring to FIG. 9, the horizontal axis represents the electron beam annealing process time (minutes), and the vertical axis represents the temperature of the substrate (°C). The solid line of the graph continuously shows a change in the increased temperature by electron beam annealing over time.

At the beginning of the electron beam annealing (0 minutes), the substrate temperature starts at room temperature of about 20°C. As the annealing progresses, the temperature of the substrate rises sharply, showing a steep temperature rise curve up to about 20 minutes. In the interval from 20 minutes to 40 minutes, the rate of temperature increase tends to gradually decrease, and after 40 minutes, the temperature becomes saturated and is stably maintained at around 180°C.

The graph clearly shows that the substrate temperature is maintained below 200°C even after 1 hour of electron beam annealing treatment. This can be confirmed in the shaded area of the graph (around 60 minutes). This temperature control satisfies the low-temperature process conditions targeted by the present disclosure, showing that effective annealing treatment is possible while preventing damage to heat-sensitive lower structures such as organic layers or thin-film transistors.

Even in the period after 60 minutes, the substrate temperature is stably maintained at 200°C or less, which shows that temperature control is effectively achieved even in a long-term process. This low-temperature electron beam annealing process is very effective in improving the crystallinity and removing defects, in each layer of the light-emitting device, especially the buffer electrode layer and the nitride semiconductor layer.

In particular, in the manufacturing of the light-emitting devices with DCS or DCIS of the present disclosure, this electron beam annealing process, which allows for such precise temperature control, may improve the quality of each layer while preventing the deterioration of the lower structure, thereby providing process conditions that are very suitable for manufacturing high-performance micro-LED displays.

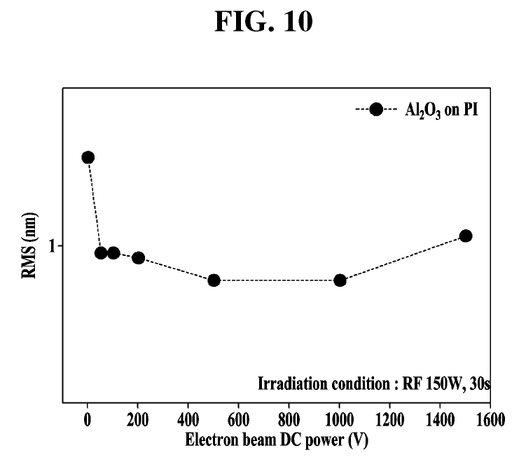

FIG. 10 is a graph illustrating a change in Root Mean Square (RMS) roughness of an Al₂O₃ thin film formed on a PI substrate according to electron beam DC power.

Referring to FIG. 10, the horizontal axis represents the electron beam DC power (V), and the vertical axis represents the RMS roughness (nm). Measurement was performed under the conditions of an RF power of 150W and an irradiation time of 30 seconds.

When the electron beam DC power is 0 V, the RMS roughness shows the highest value of about 2 nm. As the DC power increases, the RMS roughness decreases sharply and stabilizes at a level of about 1 nm in the 100 to 200 V range. Subsequently, as the DC power increases to 600V, the RMS roughness gradually decreases and is lowered to about 0.8 nm.

In the 600 to 1000 V range, the RMS roughness is constantly maintained at about 0.8 nm, showing the most stable surface characteristics. However, above 1000 V, the RMS roughness begins to increase again, rising to about 1.1 nm at 1500 V.

In FIG. 10, the effect of the electron beam DC power on the surface characteristics of the Al₂O₃ thin film on the PI substrate is clearly demonstrated. In particular, it can be seen that the DC power in the range of 600 to 1000 V provides the most excellent surface characteristics, which proves that the formation of a high-quality thin film is possible even in a low-temperature process.

Furthermore, since this surface roughness control may also greatly affect the crystallinity and electrical characteristics of subsequent layers, it is shown to be a very important process variable for optimizing the performance of the light-emitting device.

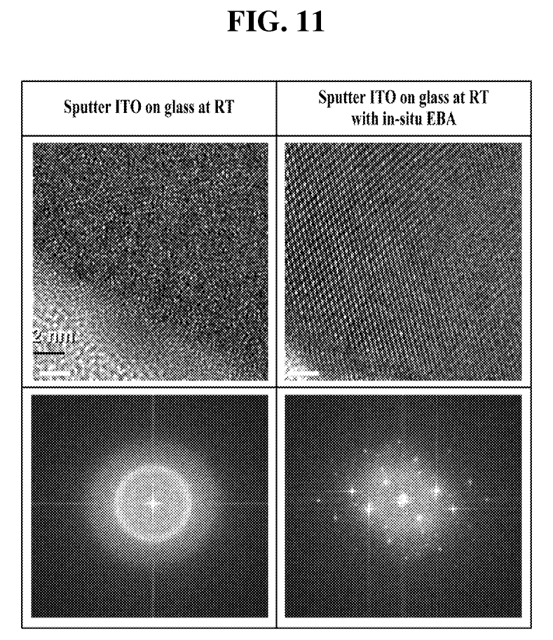

FIG. 11 compares transmission electron microscope (TEM) images and electron diffraction patterns of an ITO thin film deposited on a glass substrate at room temperature (RT) before and after electron beam annealing (EBA) treatment.

Referring to FIG. 11, the left side shows the characteristics of an ITO thin film deposited by general sputtering, and the right side shows the characteristics of an ITO thin film to which in-situ electron beam annealing was applied. The upper image for each is a high-magnification TEM image, and the lower image is the electron diffraction pattern of the corresponding area.

Referring to the TEM image of the ITO thin film deposited by general sputtering (left side), it shows an irregular crystal structure and small grain size, and it can be confirmed that the crystallinity is low. The corresponding electron diffraction pattern appears as a broad ring shape, which indicates an amorphous or very fine polycrystalline structure.

On the other hand, in the TEM image of the ITO thin film to which in-situ electron beam annealing was applied (right side), a regular and clear lattice structure is observed, and it can be confirmed that the grain size has also increased. In the corresponding electron diffraction pattern, distinct diffraction spots are observed, which proves that the crystallinity has been greatly improved.

As shown in FIG. 11, it is demonstrated that the in-situ electron beam annealing treatment is very effective in improving the crystallinity of the ITO thin film. In particular, the fact that an ITO thin film with excellent crystallinity can be formed even at room temperature proves that the low-temperature process of the present disclosure is very suitable for manufacturing light-emitting devices. The improved crystallinity leads to the improvement of electrical and optical properties, and may greatly contribute to the performance enhancement of the light-emitting device.

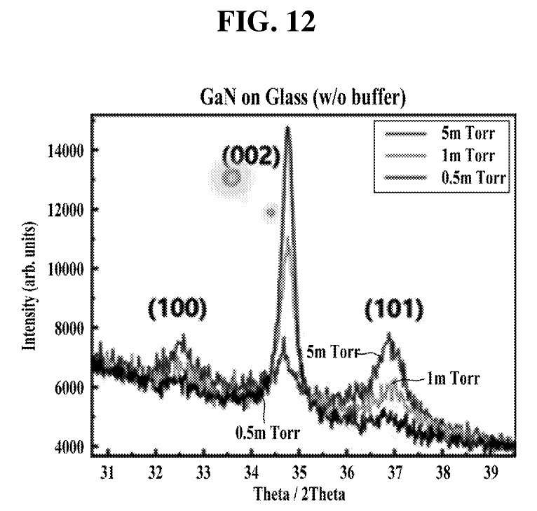

FIG. 12 is a graph illustrating X-ray diffraction (XRD) patterns according to the deposition pressure of GaN thin films deposited on a glass substrate without a buffer layer.

Referring to FIG. 12, the horizontal axis represents a diffraction angle (Theta/2Theta), and the vertical axis represents a diffraction intensity (Intensity, arbitrary units). The measurement was performed under three different deposition pressure conditions: 5 mTorr, 1 mTorr, and 0.5 mTorr.

In the XRD patterns, the (100), (002), and (101) peaks, which are the main crystal planes of GaN, are observed. The (002) peak shows the strongest intensity around about 35 degrees, which indicates a c-axis orientation. The (100) peak is observed around 33 degrees, and the (101) peak is observed around about 37 degrees.

Examining the change according to the deposition pressure, as the pressure decreases, the intensity of the (002) peak tends to increase and the full width at half maximum (FWHM) tends to decrease. At 5 mTorr, it shows a relatively low intensity and a wide FWHM, but at 0.5 mTorr, it shows the highest intensity and a narrow FWHM.

As shown in FIG. 12, the crystallinity of the GaN thin film is improved at low deposition pressures. In particular, it proves that the most excellent crystallinity can be obtained at a low pressure of 0.5 mTorr, which indicates that sputtering at an ultra-low pressure is effective for forming a high-quality GaN thin film.

Furthermore, FIG. 12 shows the structural characteristics of a GaN thin film deposited directly on a glass substrate without a buffer layer, which indirectly demonstrates the necessity and importance of a buffer layer. This explains that the introduction of the buffer electrode layer proposed in the present disclosure may play a very important role in improving crystallinity.

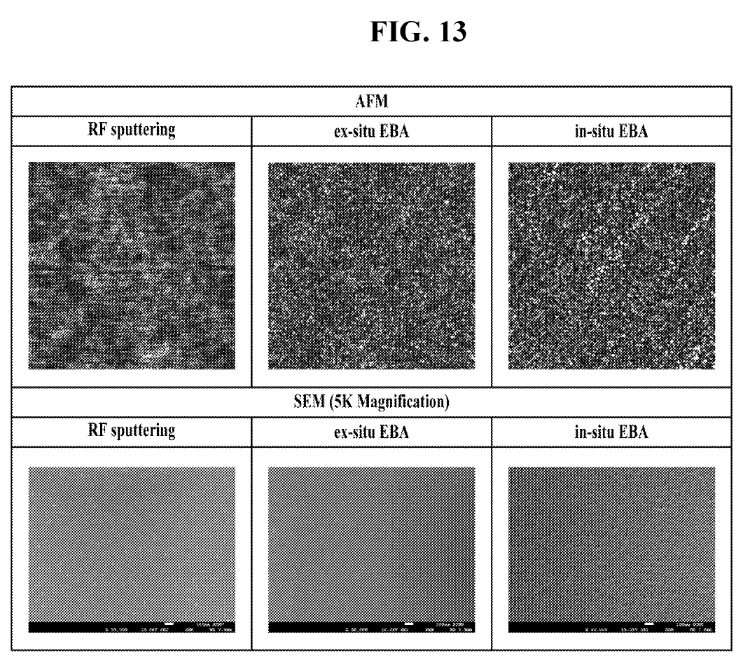

FIG. 13 compares the surface characteristics of thin films formed by RF sputtering, ex-situ electron beam annealing (EBA), and in-situ electron beam annealing processes using atomic force microscope (AFM) images and scanning electron microscope (SEM) images.

Referring to FIG. 13, the upper part shows AFM images, and the lower part shows SEM images at 5K magnification. Respective images show the surface morphologies for the case where only RF sputtering was performed (left), the case where ex-situ EBA was applied (center), and the case where in-situ EBA was applied (right).

Examining the AFM images shown in FIG. 13, the case where only RF sputtering was performed (left) shows relatively non-uniform and rough surface characteristics. In the case where ex-situ EBA was applied (center), the surface roughness is somewhat improved, but non-uniform characteristics are still observed. On the other hand, the case where in-situ EBA was applied (right) shows the most uniform and fine surface morphology.

A similar trend is observed in the SEM images shown in FIG. 13. The surface of the sample on which only RF sputtering was performed shows somewhat non-uniform characteristics, and the ex-situ EBA-treated sample shows partially improved surface characteristics. The sample to which in-situ EBA was applied shows the most uniform and dense surface morphology.

As shown in FIG. 13, it is demonstrated that the in-situ EBA process is the most effective in improving the surface characteristics of the thin film. This is interpreted to be because the electron beam annealing is performed in real-time during the deposition process, so that the crystallization and surface planarization of the thin film proceed more effectively. These excellent surface characteristics may also have a positive effect on the growth quality of subsequent layers, and thus may contribute to the overall performance improvement of the light-emitting device.

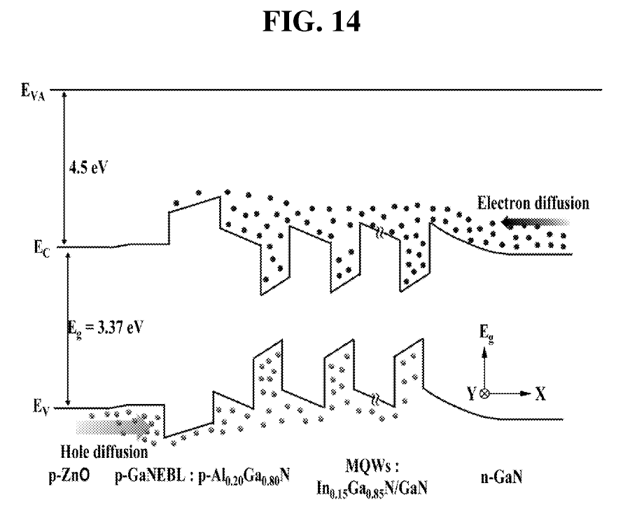

FIG. 14 illustrates the energy band diagram of a p-ZnO/p-GaN/p-AlGaN EBL/InGaN-GaN MQW/n-GaN LED structure.

Referring to FIG. 14, the energy band structure of each layer of the LED structure and the diffusion paths of electrons and holes are shown, and the entire structure is composed in the order of p-ZnO, p-GaN, an electron blocking layer (EBL: p-Al₀.₂₀Ga₀.₈₀N), a multi-quantum well layer (MQWs: In₀.₁₅Ga₀.₈₅N/GaN), and n-GaN from the left.

The bandgap (Eg) between the uppermost conduction band (EC) and the lowermost valence band (EV) is 3.37 eV, and the energy difference from the top of the valence band to the vacuum level (EVA) is 4.5 eV. Band discontinuity is observed at the interface of the respective layers, which is due to the different energy band structures of the respective materials.

Electrons diffuse from the n-GaN on the right to the left (Electron diffusion), and holes diffuse from the p-ZnO on the left to the right (Hole diffusion). In particular, the heterojunction structure of p-ZnO and p-GaN plays an important role in improving hole injection efficiency.

The multi-quantum well structure is composed of repeated layers of In₀.₁₅Ga₀.₈₅N/GaN and serves as an active layer where the recombination of electrons and holes mainly occurs. The electron blocking layer (p-Al₀.₂₀Ga₀.₈₀N) serves to prevent electron overflow and improve luminous efficiency through carrier control.

The energy band structure shown in FIG. 14 well illustrates the mechanism for improving hole injection efficiency through the heterojunction of the p-type zinc oxide layer and the p-type nitride semiconductor layer in the DCIS structure, which indicates that it can contribute to the improvement of external quantum efficiency.

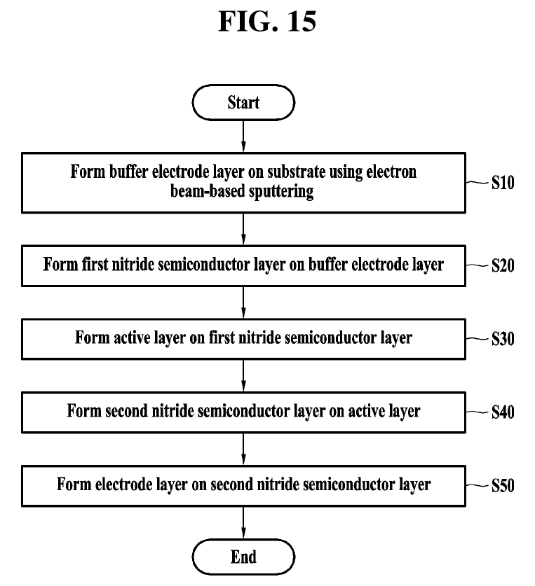

FIG. 15 is a flowchart illustrating a method of fabricating the light-emitting device according to an embodiment of the present disclosure.

Referring to FIG. 15, the fabrication process of the light-emitting device is sequentially shown from steps S10 to S50.

In step S10 of the method of fabricating the light-emitting device according to an embodiment of the present disclosure, a buffer electrode layer is formed on a substrate using electron beam-based sputtering. This process may be performed by applying curved-flight electron beam-based sputtering, electron beam-assisted sputtering, or a combination of these with electron beam annealing.

Step S10 is performed under an ultra-low pressure of 0.05 mTorr or less, and the substrate may be maintained at 200°C or less.

In the case of a light-emitting device with a DCS, the buffer electrode layer may be formed of at least one of a metal having a hexagonal crystal structure (e.g., Ti, Zr, Hf, Co, Ru, Y), an n-type transparent conductive oxide (e.g., ZnO doped with Al), and a heavily doped n-type nitride.

In the case of a light-emitting device with a DCIS, the buffer electrode layer may be formed of at least one of a metal having a high work function (e.g., Pd, Ir, Pt, Au, Ni), a metal having a hexagonal crystal structure, and a p-type transparent conductive oxide (e.g., CuCrO₂, CuScO₂, NiO, La₀.₇₅Sr₀.₂₅CrO₃).

In step S20 of the method of fabricating the light-emitting device according to an embodiment of the present disclosure, a first nitride semiconductor layer is formed on the buffer electrode layer. In the case of the DCS, an n-type nitride semiconductor layer is formed, and in the case of the DCIS structure, a p-type nitride semiconductor layer is formed.

Particularly in the DCIS, a heterojunction structure composed of a p-type zinc oxide layer and a p-type gallium nitride layer may be formed, which serves to improve hole injection efficiency and increase external quantum efficiency.

In step S30 of the method of fabricating the light-emitting device according to an embodiment of the present disclosure, an active layer is formed on the first nitride semiconductor layer. The active layer is formed with an InGaN/GaN multi-quantum well structure and serves as a light-emitting region.

In step S40 of the method of fabricating the light-emitting device according to an embodiment of the present disclosure, a second nitride semiconductor layer is formed on the active layer. In the case of the DCS structure, a p-type nitride semiconductor layer is formed, and in the case of the DCIS structure, an n-type nitride semiconductor layer is formed.

In step S50 of the method of fabricating a light-emitting device according to an embodiment of the present disclosure, an electrode layer is formed on the second nitride semiconductor layer. This electrode layer includes a transparent conductive oxide to provide a structure capable of front-side emission.

The entire process is performed at a low temperature of 200°C or less, and in particular, the electron beam-based sputtering is performed at an ultra-low pressure of 0.05 mTorr or less, enabling the formation of a high-quality thin film. This process sequence may be applied to both the DCS and DCIS structures, and appropriate materials and conditions may be selected according to each structure.

According to an embodiment, since a stable plasma can be formed even at an ultra-low pressure using electron beam-based sputtering, the mean free path of sputtered particles is increased, and thus a high-quality buffer electrode layer can be formed.

According to an embodiment, by applying a combination of a curved-flight electron beam and electron beam annealing, a buffer electrode layer having excellent crystallinity can be formed even at a low temperature of 200°C or less.

According to an embodiment, through a single-layer structure that simultaneously performs the functions of a buffer layer and an electrode layer, the manufacturing process can be simplified and manufacturing costs can be reduced, and in particular, alignment problems in fine patterns can be solved.

According to an embodiment, it can form an optimized ohmic contact with an n-type nitride semiconductor layer in a DCS structure and with a p-type nitride semiconductor layer in a DCIS structure, while also serving as a buffer layer for epitaxial growth.

According to an embodiment, since a low-temperature process is possible, a driving circuit and a light-emitting device can be directly integrated on various substrates such as glass or polymer, thereby greatly expanding the application range of micro-LED displays.

According to an embodiment, due to deposition at an ultra-low pressure, the incorporation of impurities can be minimized, and thus a light-emitting device having excellent electrical characteristics can be fabricated.

According to an embodiment, through a heterojunction structure of a p-type zinc oxide layer and a p-type gallium nitride layer in a DCIS structure, hole injection efficiency can be improved and external quantum efficiency can be increased.

According to an embodiment, by using a transparent conductive oxide as an electrode layer, a high-efficiency light-emitting device capable of front-side emission can be implemented.

Although the present disclosure has been described through limited examples and drawings, the present disclosure is not intended to be limited to the examples. Those skilled in the art will appreciate that various modifications, additions and substitutions are possible, without departing from the scope and spirit of the disclosure. Therefore, the scope of the present disclosure should not be limited to the described examples, but should be defined not only by the claims described below but also by equivalents of these claims.

What is claimed is:

1. A light-emitting device, comprising:
a substrate;
a buffer electrode layer formed on the substrate, the buffer electrode layer comprising at least one of a metal having a hexagonal crystal structure, an n-type transparent conductive oxide, and a heavily doped n-type nitride;
an n-type nitride semiconductor layer formed on the buffer electrode layer;
an active layer formed on the n-type nitride semiconductor layer;
a p-type nitride semiconductor layer formed on the active layer; and
a p-type electrode layer formed on the p-type nitride semiconductor layer,
wherein the buffer electrode layer forms an ohmic contact with the n-type nitride semiconductor layer and performs a function of a buffer layer for growth of the n-type nitride semiconductor layer.

2. The light-emitting device according to claim 1, wherein the buffer electrode layer comprises at least one metal having a hexagonal crystal structure selected from the group consisting of Ti, Zr, Hf, Co, Ru, Zn, Be, Os, Sc, and Y.

3. The light-emitting device according to claim 1, wherein the buffer electrode layer comprises an n-type transparent conductive oxide containing ZnO doped with Al.

4. The light-emitting device according to claim 1, wherein the buffer electrode layer has a structure in which a metal layer having a hexagonal crystal structure and an n-type transparent conductive oxide layer are repeatedly laminated at least two times.

5. The light-emitting device according to claim 4, wherein the buffer electrode layer comprises one of a laminated structure of the n-type transparent conductive oxide layer laminated on the metal layer having the hexagonal crystal structure, and a laminated structure of the metal layer having the hexagonal crystal structure laminated on the n-type transparent conductive oxide layer.

6. The light-emitting device according to claim 1, wherein the buffer electrode layer comprises one of a laminated structure in which the n-type transparent conductive oxide layer, the metal layer having the hexagonal crystal structure, and the n-type transparent conductive oxide layer are sequentially laminated, and a laminated structure in which the metal layer having the hexagonal crystal structure, the n-type transparent conductive oxide layer, and the metal layer having the hexagonal crystal structure are sequentially laminated.

7. The light-emitting device according to claim 1, wherein the buffer electrode layer comprises a material having a difference of 0.1 Å or less from an a-direction lattice constant of the n-type nitride semiconductor layer.

8. The light-emitting device according to claim 1, further comprising a reflective layer formed under the buffer electrode layer.

9. The light-emitting device according to claim 1, wherein the p-type electrode layer comprises a transparent conductive oxide to enable front-side emission.

10. The light-emitting device according to claim 1, wherein the p-type nitride semiconductor layer has a heterojunction structure comprising:
a p-type gallium nitride layer; and
a p-type zinc oxide layer formed on the p-type gallium nitride layer.

11. The light-emitting device according to claim 10, wherein the heterojunction structure improves hole injection efficiency and increases external quantum efficiency.

12. The light-emitting device according to claim 1, wherein the substrate comprises one of a glass substrate, a polymer substrate, a substrate comprising an amorphous layer, and a metal substrate.

13. A light-emitting device, comprising:
a substrate;
a buffer electrode layer formed on the substrate, the buffer electrode layer comprising at least one of a metal having a high work function, a metal having a hexagonal crystal structure, and a p-type transparent conductive oxide;
a p-type nitride semiconductor layer formed on the buffer electrode layer;
an active layer formed on the p-type nitride semiconductor layer;
an n-type nitride semiconductor layer formed on the active layer; and
an n-type electrode layer formed on the n-type nitride semiconductor layer,
wherein the buffer electrode layer forms an ohmic contact with the p-type nitride semiconductor layer and performs a function of a buffer layer for growth of the p-type nitride semiconductor layer.

14. The light-emitting device according to claim 13, wherein the buffer electrode layer comprises at least one metal having a high work function selected from the group consisting of Pd, Ir, Pt, Au, and Ni.

15. The light-emitting device according to claim 13, wherein the buffer electrode layer comprises at least one p-type transparent conductive oxide selected from the group consisting of Cu₂O, CuMO₂ (M=Cr, Sc, Al, Y, B, In or Ga), ZnM₂O₄ (M=Co, Rh, or Ir), NiO, SnO, V₂O₃, Cr₂O₃, SrCu₂O₂, and La₁-ₓSrₓCrO₃.

16. The light-emitting device according to claim 13, wherein the p-type nitride semiconductor layer has a heterojunction structure comprising:
a p-type zinc oxide layer formed on the buffer electrode layer; and
a p-type gallium nitride layer formed on the p-type zinc oxide layer.

17. The light-emitting device according to claim 13, wherein the heterojunction structure improves hole injection efficiency and increases external quantum efficiency.

18. The light-emitting device according to claim 13, wherein the n-type electrode layer comprises a transparent conductive oxide to enable front-side emission.

19. The light-emitting device according to claim 13, wherein the substrate comprises one of a glass substrate, a polymer substrate, a substrate comprising an amorphous layer, and a metal substrate.

20. A method of fabricating a light-emitting device, the method comprising:
forming a buffer electrode layer on a substrate using electron beam-based sputtering;
forming a first nitride semiconductor layer on the buffer electrode layer;
forming an active layer on the first nitride semiconductor layer;
forming a second nitride semiconductor layer on the active layer; and
forming an electrode layer on the second nitride semiconductor layer,
wherein the electron beam-based sputtering comprises one of curved-flight electron beam-based sputtering, electron beam-assisted sputtering, electron beam-based sputtering applying a combination of curved-flight electron beam-based sputtering and electron beam annealing, and electron beam-based sputtering applying a combination of electron beam-assisted sputtering and electron beam annealing.
